(19) United States
(12) Patent Application Publication
(10) Pub. No.: US 2012/0012379 A1
(43) Pub. Date: Jan. 19, 2012

(54) Printed circuit board

(75) Inventors: Ho-Sik Park, Hwaseong-si (KR); Keung-Jin Sohn, Seongnam-si (KR); Joon-Sik Shin, Suwon-si (KR); Sang-Youp Lee, Seoul (KR); Joung-Gul Ryu, Seoul (KR); Jung-Hwan Park, Seongnam-si (KR); Jee-Soo Mok, Yongin-si (KR)

(73) Assignee: SAMSUNG ELECTRO-MECHANICS CO., LTD., Suwon (KR)

(21) Appl. No.: 13/200,355

(22) Filed: Sep. 23, 2011

Related U.S. Application Data
(62) Division of application No. 12/285,871, filed on Oct. 15, 2008.

(30) Foreign Application Priority Data
Apr. 2, 2008 (KR) 10-2008-0030831
Aug. 6, 2008 (KR) 10-2008-0076989

(51) Int. Cl. H05K 1/11

(52) U.S. Cl. 174/262

(57) ABSTRACT

A printed circuit board including: an insulation layer; a first pattern buried in one surface of the insulation layer; a first resin layer laminated on one surface of the insulation layer to cover the first pattern; a second pattern buried in the other surface of the insulation layer; a via electrically connecting the first pattern with the second pattern; and a second resin layer laminated on the other surface of the insulation layer to cover the second pattern.

### CROSS-REFERENCE TO RELATED APPLICATIONS

This application is a U.S. divisional application filed under 37 CFR 1.53(b) claiming priority benefit of U.S. patent application Ser. No. 12/285,871 filed in the United States on Oct. 15, 2008, which claims earlier priority benefit to Korean Patent Application No. 10-2008-0030831 filed with the Korean Intellectual Property Office on Apr. 2, 2008 and Korean Patent Application No. 10-2008-0076989 filed with the Korean Intellectual Property Office on Aug. 6, 2008, the disclosures of which are incorporated herein by reference.

### BACKGROUND

1. Field

The present invention relates to a printed circuit board.

2. Description of the Related Art

With the development of the electronics industry, electronic components such as a portable device require high efficiency, high performance and miniaturization. Accordingly, studies are in progress to manufacture a printed circuit board for a high density surface mounted component, for example, a system in package (SIP) and a 3D package.

A conventional multi-layer circuit board for manufacturing a printed circuit board for a high density mounted component is manufactured through the steps of: processing a hole on a double-sided CCL (copper-clad laminate) by using a drill; plating the inside of the hole; forming a circuit pattern by etching the copper foil of both the upper and lower surfaces; interposing, heating and pressurizing prepreg, i.e., an insulating adhesive between many double-sided printed circuit boards having the circuit patterns; forming a hole at a predetermined position of the laminated multi-layer circuit board by using a drill; forming a plated layer inside the hole by plating the multi-layer circuit board so that an inner layer through is completed; and forming a desired circuit pattern by etching an outermost layer.

However, with the conventional manufacturing process of the multi-layer circuit board, it is difficult to reduce the thickness of the printed circuit board due to the complicated working process, difficulty of forming a fine pattern and the thick printed circuit board.

### SUMMARY

The present invention provides a printed circuit board that can be made thin, are highly reliable, and can be manufactured with a short lead time, and a manufacturing method thereof.

An aspect of the present invention features a method of manufacturing a printed circuit board. The method in accordance with an embodiment of the present invention can include: providing a first resin layer having a first pattern on one surface thereof; forming a conductive bump on one surface of the first resin layer, the conductive bump being electrically connected to the first pattern; compressing an insulation layer and the first resin layer such that the conductive bump passes through the insulation layer; laminating a second resin layer on the insulation layer, the second resin layer having a second pattern on a surface thereof facing the insulation layer; and forming an opening by etching a part of at least one of the first resin layer and the second resin layer.

The forming of the opening can be performed through a laser etching method or a plasma etching method.

The method can further include forming a surface treatment layer in the opening, and forming a solder ball on the surface treatment layer. At least one of the first resin layer and the second resin layer can be made of a material including one of Liquid Crystal Polymer (LCP), Polyimide (PI), Polytetrafluoroethylene (PTFE) and Polyetheretherketon (PEEK).

Particularly, when at least one of the first resin layer and the second resin layer is made of a material including the Polyimide (PI), the insulation layer can be made of a material including Liquid Crystal Polymer (LCP).

Also, the first resin layer, the insulation layer and the second resin layer can be all made of a material including liquid crystal polymer. In this case, the insulation layer can have a lower melting point than those of the first resin layer and the second resin layer.

At least one of the first resin layer and the second resin layer can be a photo solder resist (PSR) and the forming of the opening can be performed by exposing the photo solder resist to light and developing the photo solder resist.

At least one of the first pattern and the second pattern can be formed by laminating a metal layer on one surface of the photo solder resist; forming a first photosensitive material layer on the metal layer; selectively exposing to light and developing the first photosensitive material layer; etching the metal layer; and removing the first photosensitive material layer.

The method can further include forming a second photosensitive material layer on the other surface of the photo solder resist, and further include removing the second photosensitive material layer before the forming of the opening.

The photo solder resist can further include a protective layer on the other surface thereof, and can further include removing the protective layer before the forming of the opening. In this case, the protective layer can be made of a material including polyethylene terephthalate (PET). The protective layer can be opaque.

Another aspect of the present invention features a printed circuit board. The printed circuit board in accordance with an embodiment of the present invention can include: an insulation layer; a first pattern buried in one surface of the insulation layer; a first resin layer laminated on one surface of the insulation layer to cover the first pattern; a second pattern buried in the other surface of the insulation layer; a via electrically connecting the first pattern to the second pattern; and a second resin layer laminated on the other surface of the insulation layer to cover the second pattern.

At least one of the first resin layer and the second resin layer is made of a material including one of Liquid Crystal Polymer (LCP), Polyimide (PI), Polytetrafluoroethylene (PTFE), Polyetheretherketon (PEEK) and photo solder resist (PSR).

Particularly, when at least one of the first resin layer and the second resin layer is made of a material including Polyimide (PI), the insulation layer can be made of a material including Liquid Crystal Polymer (LCP).

The first resin layer, the insulation layer and the second resin layer can be all made of a material including liquid crystal polymer. In this case, the insulation layer can have a lower melting point than those of the first resin layer and the second resin layer.

The via can be a bump formed by curing conductive paste. An opening can be formed on the first resin layer such that a part of the first pattern is exposed. In this case, a solder ball can be formed in the opening.

Yet another aspect of the present invention features a method of manufacturing a printed circuit board. The method of manufacturing printed circuit board in accordance with an embodiment of the present invention can include: providing a first resin layer having a first pattern on one surface thereof; forming a first conductive bump on the one surface of the first resin layer, the first conductive bump being electrically connected to the first pattern; interposing a first insulation layer and compressing one surface of the first resin layer and one surface of an inner layer substrate part; and forming an opening by etching a part of the first resin layer.

Also, the printed circuit board manufacturing method can further perform: providing a second resin layer having a second pattern on one surface thereof; forming a second conductive bump on the one surface of the second resin layer, the second conductive bump being electrically connected to the second pattern; interposing a second insulation layer and compressing one surface of the second resin layer and the other surface of the inner layer substrate part; and forming an opening by etching a part of the second resin layer.

The first resin layer can be made of a material including one of Liquid Crystal Polymer (LCP), Polyimide (PI), Polytetrafluoroethylene (PTFE) and Polyetheretherketon (PEEK).

Particularly, when the first resin layer is made of a material including Polyimide (PI), the first insulation layer can be made of a material including Liquid Crystal Polymer (LCP).

The first resin layer is a photo solder resist, and the forming of the opening can be performed by exposing the photo solder resist to light and developing the photo solder resist.

Here, the first pattern can be formed by laminating a metal layer on one surface of the photo solder resist; forming a photosensitive material layer on the metal layer; selectively exposing to light and developing the photosensitive material layer; etching the metal layer; and removing the photosensitive material layer.

The method can further include forming a second photosensitive material layer on the other surface of the photo solder resist, and further include removing the second photosensitive material layer before the forming of the opening.

The photo solder resist can further include a protective layer on the other surface thereof, and can further include removing the protective layer before the forming of the opening. In this case, the protective layer can be made of a material including polyethylene terephthalate (PET). The protective layer can be opaque.

Still another aspect of the present invention features a printed circuit board. The printed circuit board in accordance with an embodiment of the present invention can include: an inner layer substrate part; a first insulation layer laminated on one surface of the inner layer substrate part; a first pattern buried in one surface of the first insulation layer; a first resin layer laminated on one surface of the first insulation layer to cover the first pattern; and a first via electrically connecting the first pattern with the inner layer substrate part. The first resin layer is made of a material comprising one of Liquid Crystal Polymer (LCP), Polyimide (PI), Polytetrafluoroethylene (PTFE). Polyetheretherketon (PEEK) and a photo solder resist.

The printed circuit board can further include: a second insulation layer laminated on the other surface of the inner layer substrate part; a second pattern buried in the other surface of the second insulation layer; a second resin layer laminated on the other surface of the second insulation layer to cover the second pattern; and a second via electrically connecting the second pattern with the inner layer substrate part.

When the first resin layer is made of a material including Polyimide (PI), the first insulation layer can be made of a material including Liquid Crystal Polymer (LCP).

### BRIEF DESCRIPTION OF THE DRAWINGS

FIG. 1 illustrates a flowchart showing a method of manufacturing a printed circuit board according to an embodiment of the present invention.

FIGS. 2 to 8 illustrate cross sectional views showing each process of a method of manufacturing a printed circuit board according to an embodiment of the present invention.

FIG. 9 illustrates a flowchart showing a method of manufacturing a printed circuit board according to another embodiment of the present invention.

FIGS. 10 to 16 illustrate cross sectional views showing each process of a method of manufacturing a printed circuit board according to another embodiment of the present invention.

FIG. 17 illustrates a flowchart showing a method of manufacturing a printed circuit board according to yet another embodiment of the present invention.

FIGS. 18 to 28 illustrate cross sectional views showing each process of a method of manufacturing a printed circuit board according to yet another embodiment of the present invention.

### DESCRIPTION OF EMBODIMENTS

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. In the following description of the present invention, the detailed description of known technologies incorporated herein will be omitted when it may make the subject matter unclear.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, certain embodiments of a printed circuit board and a manufacturing method thereof according to the present invention will be described in detail with reference to the accompanying drawings. Throughout the following description with reference to the accompanying drawings, identical or corresponding elements will be given the same reference numerals, and any redundant description of the identical or corresponding elements will not be repeated.

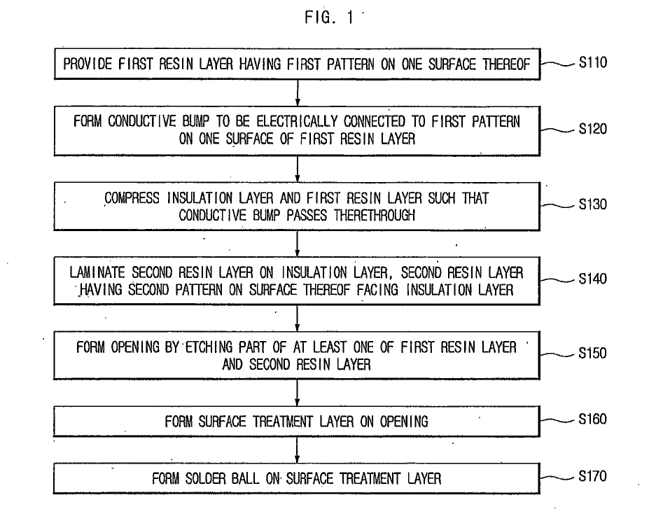

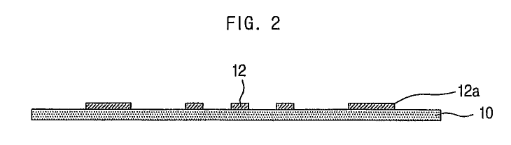

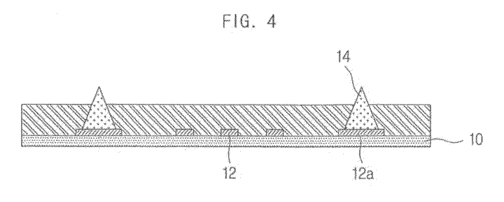

FIG. 1 illustrates a flowchart showing a method of manufacturing a printed circuit board according to an embodiment of the present invention. FIGS. 2 to 8 illustrate cross section views showing each process of a method of manufacturing a printed circuit board according to an embodiment of the present invention. Illustrated in FIGS. 2 to 8 are a first resin layer 10, openings 11 and 21, a first pattern 12, a first pad 12a, surface treatment layers 13 and 23, a conductive bump 34, a second resin layer 20, a second pattern 22, a second pad 22a, an insulation layer 30 and a solder ball 40.

First, as illustrated in FIG. 2, the first resin layer 10 having the first pattern 12 on one surface thereof is provided in the step represented by S110. In order to form the first pattern 12, after either a substrate of resin coated copper (RCC) including the first resin layer 10 and a copper foil laminated on the first resin layer 10 or a substrate of flexible copper clad laminate (FCCL) is prepared, a part of the copper foil may be etched. It is also possible to plate the copper foil.

The main material of the first resin layer 10 can be any one of Liquid Crystal Polymer (LCP), Polyimide (PI), Polytetrafluoroethylene (PTFE) and Polyetheretherketon (PEEK).

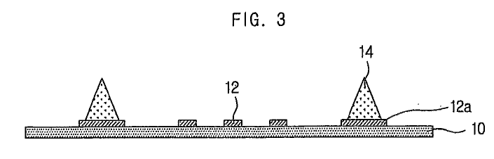

Then, as illustrated in FIG. 3, after the conductive bump 34, which is electrically connected to the first pattern 12, is formed on one surface of the first resin layer 10 in the step represented by S120, the insulation layer 30 and the first resin layer 10 are compressed such that the conductive bump 34 passes through the insulation layer 30 in the step represented by S130.

The conductive bump 34 can be formed on a pad, which is a part of the first pattern 12, and function as a via for an inner layer through by passing through the insulation layer 30. Such a conductive bump 34 can be formed by printing a conductive material through a screen printing process or an ink jet printing process and then curing the printed conductive material.

The insulation layer 30 can be selectively used according to the kind of the first resin layer 10. For example, if the main material of the first resin layer 10 is Polyimide (PI), liquid crystal polymer film can be used as the insulation layer 30. If the main material of the first resin layer 10 is liquid crystal polymer (LCP), liquid crystal polymer film of the same kind with a melting point that is lower by as much as about 30° C. to 70° C. can be used as the insulation layer 30. It is also possible that prepreg and ABF are used as the insulation layer 30.

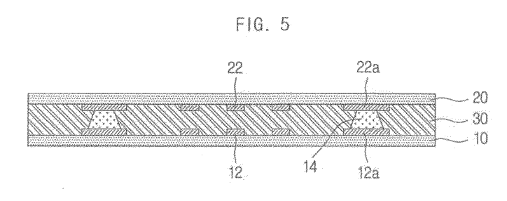

Then, as illustrated in FIG. 5, the second resin layer 20 having the second pattern 22 on the surface thereof facing the insulation layer 30 is laminated on the insulation layer 30 in the step represented by S140. The second pattern 22 and the upper part of the conductive bump 34 can be in contact with each other, and as a result the first pattern 12 can be electrically connected to the second pattern 22. Like the first pattern 12, the second pattern 22 can be also buried in the insulation layer 30.

If prepreg and ABF are used as the insulation layer 30, the main material of the second resin layer 20 can be any one of Liquid Crystal Polymer (LCP), Polyimide (PI), Polytetrafluoroethylene (PTFE) and Polyetheretherketon (PEEK), like the first resin layer 10. If an LCP having a low melting point (between about 260° C. and 280° C.) is used as the insulation layer 30, an LCP having a higher melting point by 30° C. to 50° C. than that of the insulation layer 30 can be used as the second resin layer 20.

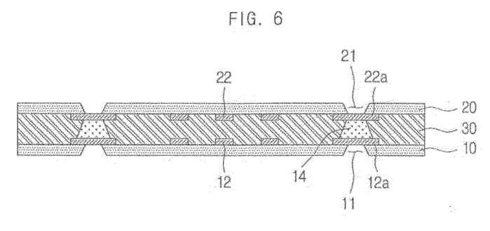

Subsequently, the openings 11 and 21 are formed by etching a part of at least one of the first resin layer 10 and the second resin layer 20 in the step represented by S150. A laser etching method and a plasma etching method, as well as various other methods, can be employed to form the openings 11 and 21. As illustrated in FIG. 6, while the openings 11 and 21 are formed on both the first resin layer 10 and the second resin layer 20, there can be various numbers and locations of the openings 11 and 21, depending on the design.

Meanwhile, the first resin layer 10 and the second resin layer 20 are not entirely removed, and can function to protect the first pattern 12 and the second pattern 22. That is, an existing solder resist can be substituted by the first resin layer 10 and the second resin layer 20, thereby simplifying the process with no necessity of performing an extra process for forming the solder resist so that it is possible to remarkably reduce a lead time.

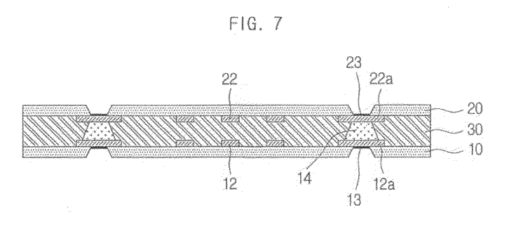

Then, as illustrated in FIG. 7, surface treatment layers 13 and 23 are formed on the pads 12a and 22a, which are exposed by the openings 11 and 21, in the step represented by S160, and solder balls 40 are formed on the surface treatment layers 13 and 23 in the step represented by S170. Accordingly, it is possible to construct a structure that is capable of providing electrical connection to a mother board or an electronic element such as a semiconductor chip. In order to form the surface treatment layers 13 and 23, nickel/gold plating, OSP processing, ENIG or ENEPIG, etc., can be used.

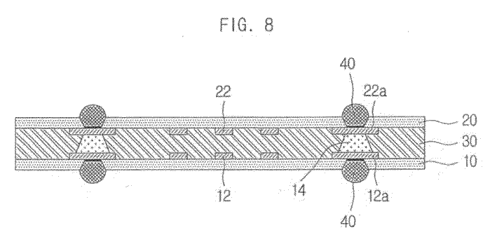

The printed circuit board manufactured as described above is illustrated in FIG. 8. The printed circuit board manufactured by the process described above can mainly include the insulation layer 30, the first pattern 12, which is buried in one surface of the insulation layer 30, the first resin layer 10, which is laminated on the one surface of the insulation layer 30 and configured to cover the first pattern 12, the second pattern 22, which is buried in the other surface of the insulation layer 30, the via electrically connecting the first pattern 12 with the second pattern 22, and the second resin layer 20, which is laminated on the other surface of the insulation layer 30 and configured to cover the second pattern 22. The main material of at least one of the first resin layer 10 and the second resin layer 20 can be any one of Liquid Crystal Polymer (LCP), Polyimide (PI), Polytetrafluoroethylene (PTFE) and Polyetheretherketon (PEEK).

While a printed circuit board according to a related art protects an outer layer by using a solder resist having a coefficient of thermal expansion of more than 50 ppm/t, the printed circuit board according to this embodiment of the present invention presents a configuration which protects the pattern of the outer layer by using materials, such as Liquid Crystal Polymer (LCP), Polyimide (PI), Polytetrafluoroethylene (PTFE) and Polyetheretherketon (PEEK), which have relatively low coefficient of thermal expansion.

By substituting a conventional solder resist by a material having a low coefficient of thermal expansion, it is possible to the coefficient of thermal expansion can be reduced to between ½ and 1/10 times of the coefficient of thermal expansion of the conventional solder resist.

The thinner the printed circuit board becomes, the greater the ratio of the thickness of the solder resist protecting the pattern of the outer layer becomes. Thus, substitution of the conventional solder resist by a material having a low coefficient of thermal expansion can have a great significance in manufacturing the printed circuit board having a low coefficient of thermal expansion.

In addition, by implementing an inner layer connection using a conductive bump 34 as a via, which is formed by printing and curing the conductive paste, it is possible to simplify the manufacturing process, thereby reducing a lead time.

If the first resin layer 10, the insulation layer 30 and the second resin layer 20 are all made of liquid crystal polymer, it is also possible to implement a thin printed circuit board that is highly dielectric.

Next, a method of manufacturing a printed circuit board according to another embodiment of the present invention will be described.

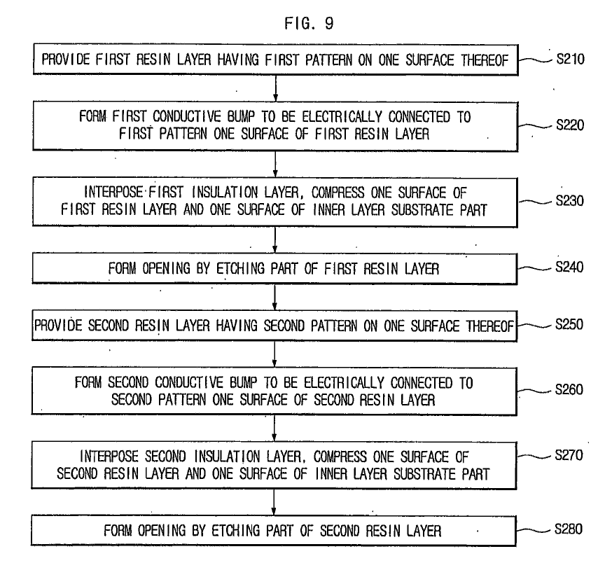

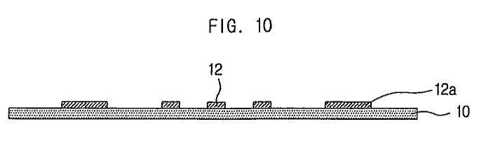

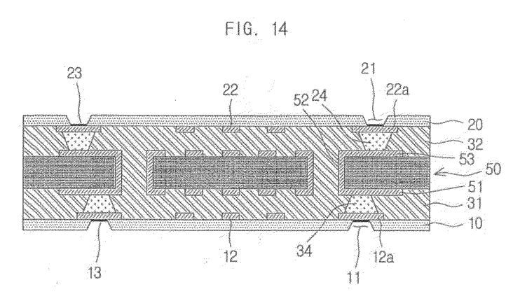

FIG. 9 illustrates a flowchart showing a method of manufacturing a printed circuit board manufacturing method according to another embodiment of the present invention. FIGS. 10 to 16 illustrate cross section views showing each process of a method of manufacturing a printed circuit board according to another embodiment of the present invention. Illustrated in FIGS. 10 to 16 are a first resin layer 10, openings 11 and 21, a first pattern 12, a first pad 12a, surface treatment layers 13 and 23, a first conductive bump 34, a second resin layer 20, a second pattern 22, a second pad 22a, a second conductive bump 24, a first insulation layer 31, a second insulation layer 32, a solder ball 40, an inner layer substrate part 50, an inner layer circuits 51 and 53 and a via 52.

The method of manufacturing the printed circuit board according to this embodiment differs from the manufacturing method of the embodiment described above in that the printed circuit board has more than two layers. Hereinafter, the difference from the embodiment described above will be described, and description of identical or corresponding elements will not be repeated.

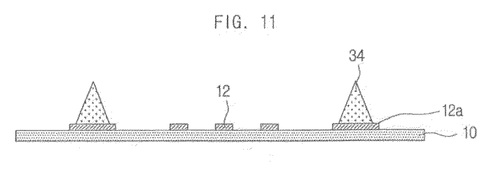

First, as illustrated in FIG. 10, the first resin layer 10 having the first pattern 12 on one surface thereof is provided in the step represented by S210. As illustrated in FIG. 11, the first conductive bump 34, which is electrically connected to the first pattern 12, is formed on one surface of the first resin layer 10 in the step represented by S220.

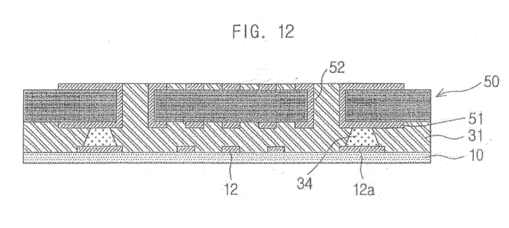

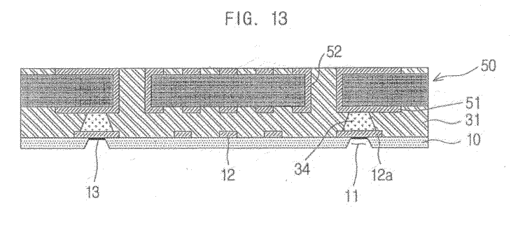

Then, as illustrated in FIG. 12, the first insulation layer 31 is interposed, and becomes compressed by one surface of the first resin layer 10 and one surface of the inner layer substrate part 50, in the step represented by S230. Subsequently, as illustrated in FIG. 13, the opening 11 is formed by etching a part of the first resin layer 10 in the step represented by S240.

The second resin layer 20 having the second pattern 22 on one surface thereof is provided in the step represented by S250, and the second conductive bump 24, which is electrically connected to the second pattern 22, is formed on one surface of the second resin layer 20 in the step represented by S260. Then, the second insulation layer 32 is interposed, and becomes compressed by one surface of the second resin layer 20 and the other surface of the inner layer substrate part 50, in the step represented by S270.

Subsequently, the opening 21 can be formed by etching a part of the second resin layer 20 in the step represented by S280.

Thereafter, the solder ball 40 is formed in each of the openings 11 and 21, constructing a structure capable of providing electrical connection to a mother board or an electronic element such as a semiconductor chip.

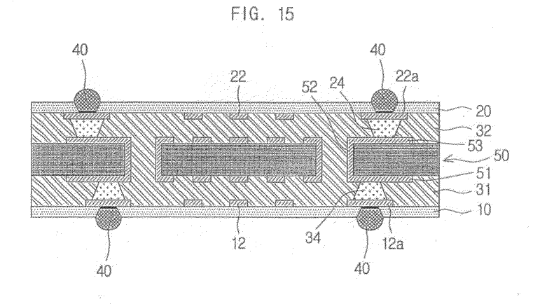

The printed circuit board manufactured through the above process is illustrated in FIG. 15.

With this embodiment, the inner layer substrate part 50 is located between the first resin layer 10 and the second resin layer 20, unlike the earlier embodiment. By varying the configuration of the inner layer substrate part 50 and the number of layers, it is possible to manufacture a multi-layer printed circuit board of any number of layers. The inner layer substrate part 50 can accommodate the via 52 and inner layer circuits 51 and 53.

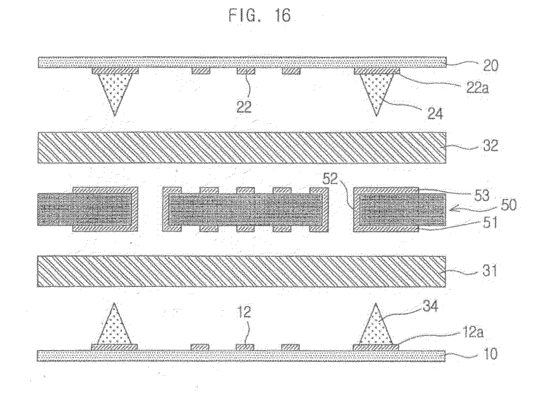

While the first resin layer 10 and the second resin layer 20 are sequentially compressed with both sides of the inner layer substrate part 50 in FIGS. 10 to 15, it is also possible to collectively laminate the layers, as illustrated in FIG. 16.

In the following description, a method of manufacturing a printed circuit board according to yet another embodiment of the present invention will be described.

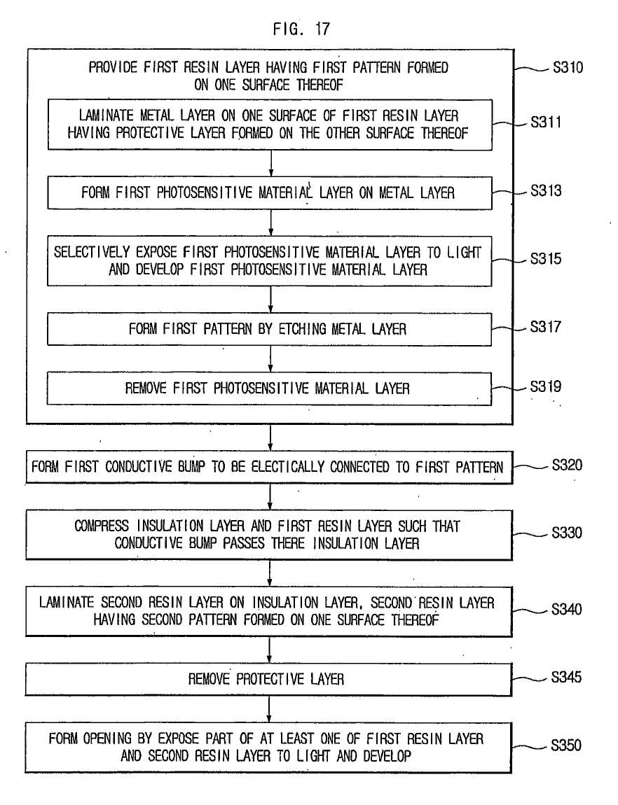

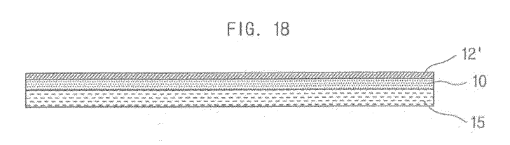

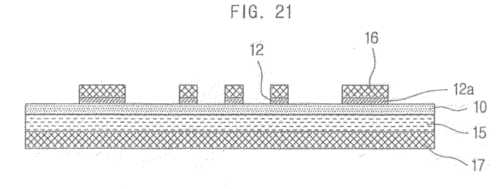

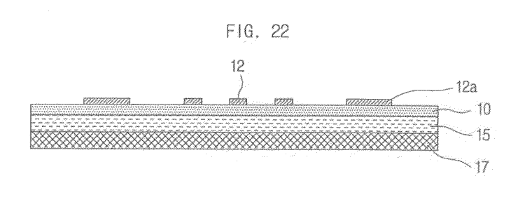

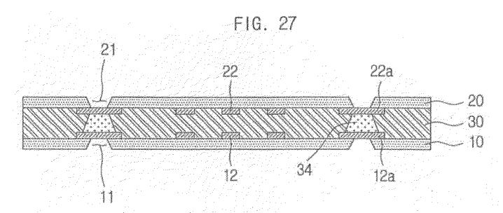

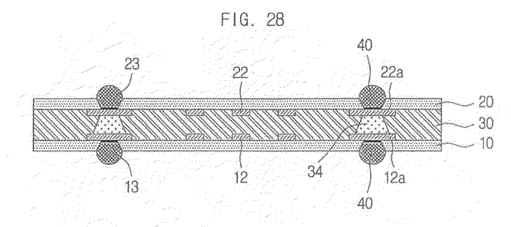

FIG. 17 illustrates a flowchart showing a method of manufacturing a printed circuit board according to yet another embodiment of the present invention. FIGS. 18 to 28 illustrate cross sectional views showing each process of a method of manufacturing a printed circuit board according to yet another embodiment of the present invention. Illustrated in FIGS. 18 to 28 are a first resin layer 10, openings 11 and 21, a metal layer 12′, a first pattern 12, a first pad 12a, protective layers 15 and 25, a first photosensitive material layer 26, second photosensitive material layers 17 and 27, a second resin layer 20, a second pattern 22, a second pad 22a, an insulation layer 30, a conductive bump 34 and a solder ball 40.

The embodiment of the present invention features that at least one of the first resin layer 10 and the second resin layer 20 is a photo solder resist.

First, the first resin layer 10 having the first pattern 12 is formed on one surface thereof in the step represented by S310. A subtractive method can be used in order to form the first pattern 12.

As illustrated in FIG. 18, the metal layer 12′ is laminated on one surface of the first resin layer 10, which has the protective layer 15 formed on the other surface thereof, in the step represented by S311. Since the metal layer 12′ is etched to become a circuit pattern of the printed circuit board, a conductive material, such as copper (Cu) or gold (Au), can be used.

The protective layer 15 is later removed when the manufacturing of a substrate is completed and is not absolutely necessary. However, by using the photo solder resist, on which the protective layer 15 is formed on the other surface thereof, the process of forming a substrate can be much more stable because the protective layer functions similar to a carrier so as to protect the photo solder resist.

The protective layer 15 can be made of a material including polyethylene terephthalate (PET). If the protective layer 15 is particularly made of an opaque material, the photo solder resist can be protected from being exposed to light during the process of exposing the photosensitive material layer to light when forming a pattern by etching in subsequent steps.

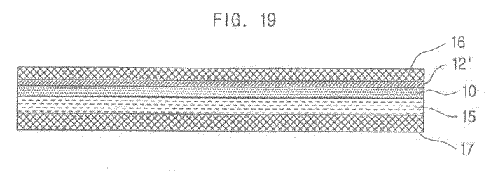

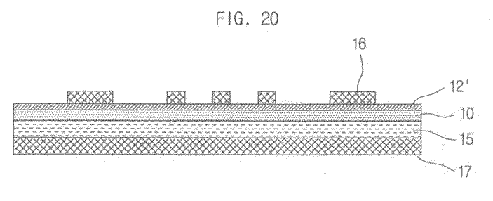

Then, as illustrated in FIGS. 19 and 20, the first photosensitive material layer 16 is formed on the metal layer 12′ and then is selectively exposed to light and developed, in the steps represented by S313 and S315. The first photosensitive material layer is exposed to light and developed such that it remains on the metal layer 12′ in the shape corresponding to that of the first pattern 12. The second photosensitive material layer 17 can be formed on the other surface of the first resin layer 10, or on the other surface of the protective layer 15 if the protective layer 15 does exist. The second photosensitive material layer 17 cured by being exposed to light can strengthen any weak intensity because the protective layer 15 functions as a carrier.

Next, the metal layer 12′ is etched to form the first pattern 12, and then the first photosensitive material layer 16 is removed in the steps represented by S317 and S319. Since the metal layer 12′ in the area where the first photosensitive material remains is protected during the etching, the metal layer 12′ exposed to the surface by removing the first photosensitive material layer 16 after etching becomes the first pattern 12 (see reference numerals 21 and 22).

This process can be also applied to form not only the first pattern 12 but also the second pattern 22 in the same manner.

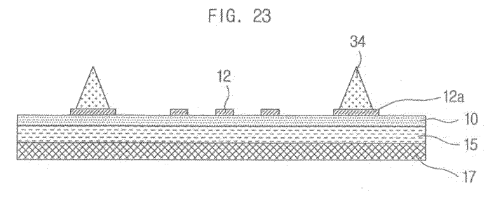

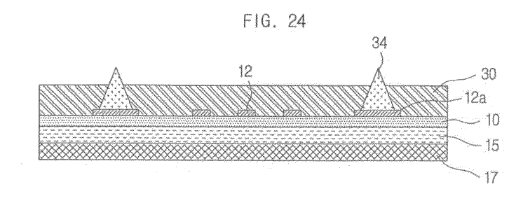

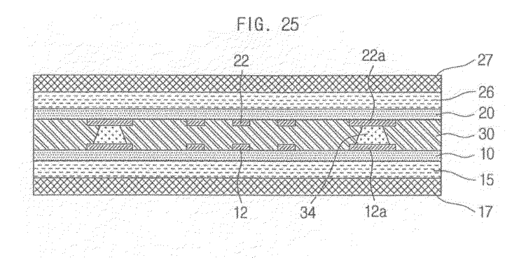

Then, as illustrated in FIG. 23, the first conductive bump 34, which is electrically connected to the first pattern 12, is formed in the step represented by S320. The insulation layer 30 and the first resin layer 10 are compressed such that the conductive bump 34 passes through the insulation layer 30 in the step represented by S330, as illustrated in FIG. 24. Subsequently, as illustrated in FIG. 25, the second resin layer 20, which has the second pattern 22 formed on the surface thereof facing the insulation layer 30, is laminated on the insulation layer 30 in the step represented by S340.

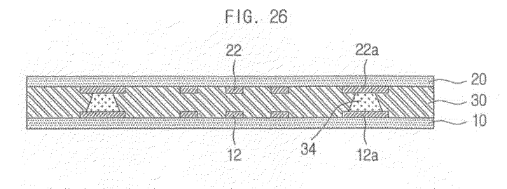

The first resin layer 10 and the second resin layer 20 are then exposed by removing the protective layer 15 in the step represented by S345. When the substrate surface treatment process is left to be performed only, the protective layer 15 and the second photosensitive material layer 17 are not needed any more. Accordingly, the protective layer 15 and the second photosensitive material layer 17 are removed. As illustrated in FIG. 26, when the second photosensitive material layer 17 is formed on the protective layer 15, the photosensitive material layer 17 can be removed together with the protective layer 15.

A part of at least one of the first resin layer 10 and the second resin layer 20 is exposed to light and developed such that the opening is formed in the step represented by S350. Unlike the embodiment described above, since at least one of the first resin layer 10 and the second resin layer 20 is a photo solder resist, the part of at least one of the first resin layer 10 and the second resin layer 20 is selectively removed by being exposed to light and developed such that the opening can be formed without a drilling process or a laser process. Each of the openings 11 and 21 has a solder ball 40 formed therein so that it is possible to construct a structure capable of providing electrical connection to a mother board or an electronic element such as a semiconductor chip.

Illustrated in FIG. 26 is a printed circuit board manufactured through the process.

Since it is not necessary to separately form a solder resist in this embodiment of the present invention, the lead time can be reduced. Moreover, since the first resin layer 10 and the second resin layer 20 are photo solder resists, the drilling process is unnecessary during the forming of an opening, causing less damage to the pattern. In addition, because the protective layer 15 and the second photosensitive material layer 17 can function as a carrier, it is possible to perform a process of forming the printed circuit board without using a separate carrier.

That is, an existing solder resist can be substituted by the first resin layer 10 and the second resin layer 20, thereby simplifying the process without performing an extra process of forming the solder resist and thus remarkably reducing the lead time.

While the present invention has been described with reference to certain embodiments thereof, it will be understood by those skilled in the art that various changes and modification in forms and details may be made without departing from the spirit and scope of the present invention as defined by the appended claims.

Numerous embodiments other than the embodiments described above are included within the scope of the present invention.

What is claimed is:

1. A printed circuit board comprising:
an insulation layer;
a first pattern buried in one surface of the insulation layer;
a first resin layer laminated on one surface of the insulation layer to cover the first pattern;
a second pattern buried in the other surface of the insulation layer;
a via electrically connecting the first pattern with the second pattern; and
a second resin layer laminated on the other surface of the insulation layer to cover the second pattern.

2. The printed circuit board of claim 1, wherein at least one of the first resin layer and the second resin layer is made of a material comprising one of Liquid Crystal Polymer (LCP), Polyimide (PI), Polytetrafluoroethylene (PTFE), Polyetheretherketon (PEEK) and photo solder resist (PSR).

3. The printed circuit board of claim 1, wherein at least one of the first resin layer and the second resin layer is made of a material comprising Polyimide (PI) the insulation layer is made of a material comprising Liquid Crystal Polymer (LCP).

4. The printed circuit board of claim 1, wherein the first resin layer, the insulation layer and the second resin layer are all made of a material including liquid crystal polymer.

5. The printed circuit board of claim 4, wherein the insulation layer has a lower melting point than those of the first resin layer and the second resin layer.

6. The printed circuit board of claim 1, wherein the via is a bump formed by curing conductive paste.

7. The printed circuit board of claim 1, wherein an opening is formed on the first resin layer such that a part of the first pattern is exposed.

8. The printed circuit board of claim 7, wherein a solder ball is formed in the opening.
